(19) United States
(12) Patent Application Publication
(10) Pub. No.: US 2026/0223602 A1
(43) Pub. Date: Jul. 30, 2026

(54) SENSOR DEVICE, PRODUCTION METHOD FOR A SENSOR DEVICE, AND OPERATION METHOD FOR A SENSOR DEVICE

(71) Applicant: Robert Bosch GmbH, Stuttgart (DE)

(72) Inventors: David Slogsnat, Tuebingen (DE); Manuel Glas, Kirchentellinsfurt (DE); Timo Giesselmann, Stuttgart (DE); Tuomas Hollman, Espoo (FI)

(21) Appl. No.: 19/439,521

(22) Filed: Jan. 5, 2026

(30) Foreign Application Priority Data
Jan. 9, 2025 (DE) 10 2025 100 541.9

(51) Int. Cl. H10N 50/10; H10N 50/80; H10N 59/00

(52) U.S. Cl. CPC H10N 50/10; H10N 50/80; H10N 59/00

(57) ABSTRACT

A sensor device. The sensor device includes at least one first substrate having a first substrate surface; a sensor element layer having at least one sensitive element arranged in the sensor element layer, wherein the sensor element layer covers the first substrate surface and/or at least one intermediate layer at least partially covering the first substrate surface; and at least one capacitor apparatus, wherein the at least one capacitor apparatus is formed in the first substrate and/or in a second substrate which is electrically connected to the first substrate via at least one bonding connection. A production method for a sensor device, and an operation method for a sensor device, are also described.

### CROSS REFERENCE

The present application claims the benefit under 35 U.S.C. § 119 of Germany Patent Application No. DE 10 2025 100 541.9 filed on January 9, 2025, which is expressly incorporated herein by reference in its entirety.

### FIELD

The present invention relates to a sensor device. The present invention also relates to a production method for a sensor device. In addition, the present invention relates to an operation method for a sensor device.

### BACKGROUND INFORMATION

FIG. 1 is a schematic partial representation of a conventional magnetic sensor.

The magnetic sensor shown in FIG. 1, which is partially represented as related art, can be referred to as a BMM350 magnetometer (see www.bosch-sensortec.com\products\motion-sensors\magnetometers\bmm350\). The conventional magnetic sensor has a circuit board 10 on which, in addition to a BMM350 sensor 12, three capacitors 14 are mounted.

### SUMMARY

The present invention provides a sensor device, a production method, and an operation method for a sensor device. According to an example embodiment, the sensor device includes: at least one first substrate having a first substrate surface; a sensor element layer having at least one sensitive element arranged in the sensor element layer, wherein the sensor element layer covers the first substrate surface and/or at least one intermediate layer at least partially covering the first substrate surface; and at least one capacitor apparatus; wherein the at least one capacitor apparatus is formed in the first substrate and/or in a second substrate which is electrically connected to the first substrate via at least one bonding connection.

The present invention provides sensor devices each having at least one capacitor apparatus which can be made smaller than standard sensors having at least one capacitor without significant additional effort. The present invention thus advantageously contributes to the miniaturization of sensor devices, each having at least one capacitor apparatus. The present invention thus also expands the applicability of sensor devices for different purposes. Furthermore, the miniaturization of sensor devices, realized according to the invention, can contribute to material savings in the particular sensor device, making the sensor device according to the invention more cost-effective to produce.

In an advantageous embodiment, the sensor device is designed and/or programmed such that at least one component of the sensor device can be powered using a charge temporarily stored on the at least one capacitor apparatus. The at least one capacitor apparatus formed in a space-saving manner in the first substrate and/or in the second substrate can thus be advantageously used as an energy store/current store. In particular, the sensor device can be designed and/or programmed such that at least one measurement bridge having the at least one sensitive element, and/or an application-specific integrated circuit of the sensor device, as the at least one component of the sensor device, can be powered, using a charge temporarily stored on the at least one capacitor apparatus, such that a particular supply voltage of the at least one measurement bridge and/or the application-specific integrated circuit can be stabilized.

In a further advantageous embodiment of the sensor device of the disclosure, the at least one capacitor apparatus is formed in the second substrate, wherein the at least one bonding connection, via which the second substrate is electrically connected to the first substrate, is electrically connected to at least one electrical through-contact which extends through the first substrate and/or the second substrate. This allows the two substrates of the embodiment of the sensor device described here to be integrated into a chip-scale package in a space-saving manner.

Preferably, the at least one intermediate layer at least partially covering the first substrate surface comprises at least one circuit layer having an application-specific integrated circuit. The embodiment of the sensor device described here can therefore be described as a sensor device integrated into an ASIC. Integrating the embodiment of the sensor device described here into a mold package is therefore easily achievable.

As an advantageous development, the sensor device can also comprise a redistribution layer at least partially covering the sensor element layer or a second substrate surface of the second substrate. Equipping the sensor device with the redistribution layer also facilitates its implementation as a single chip-scale package.

Carrying out a corresponding production method for a sensor device also realizes the advantages described above. In particular, when carrying out the production method, at least one capacitor apparatus can be formed in the first substrate and/or in the second substrate by means of deep-trench technology. The at least one capacitor apparatus can thus be designed as an advantageous silicon capacitor in the first substrate and/or in the second substrate.

Furthermore, carrying out a corresponding operation method for a sensor device also provides the advantages explained above. It is expressly noted that the operation method for a sensor device can be further formed in accordance with the above-described embodiments of the sensor device and/or the production method.

Preferably, at least one conductor component, as the at least one component of the sensor device, is powered, using a charge temporarily stored on the at least one capacitor apparatus, such that a magnetic field is generated, by means of which a particular polarization of a particular free layer of at least one sensitive element designed as a magnetoresistive element is generated. The "generation" of polarization can also be understood as the "restoration" of polarization. The embodiment of the method described here is therefore well suited for what is known as a magnetic reset, by means of which the at least one magnetoresistive element used for a magnetoresistive measurement method can recover from a strong external magnetic field, in particular from what is known as a magnetic shock, and a performance of the sensor device used as a magnetic sensor device can be optimized.

Alternatively or additionally, at least one measurement bridge having the at least one sensitive element, and/or an application-specific integrated circuit of the sensor device, as the at least one component of the sensor device, can be powered, using a charge temporarily stored on the at least one capacitor apparatus, such that a particular supply voltage of the at least one measurement bridge and/or the application-specific integrated circuit is stabilized. In this way as well, operation of the sensor device described here can be improved.

### BRIEF DESCRIPTION OF THE DRAWINGS

Further features and advantages of the invention will be explained in the following with reference to the figures.

FIG. 1 is a schematic partial representation of a conventional magnetic sensor.

FIG. 2 is a schematic representation of a first embodiment of the sensor device of the disclosure.

FIG. 3A and 3B are schematic representations of a second embodiment of the sensor device of the disclosure.

FIG. 4 is a schematic representation of a third embodiment of the sensor device of the disclosure.

FIG. 5 is a flow chart explaining an embodiment of the production method for a sensor device.

FIG. 6 is a flow chart explaining an embodiment of the operation method for a sensor device.

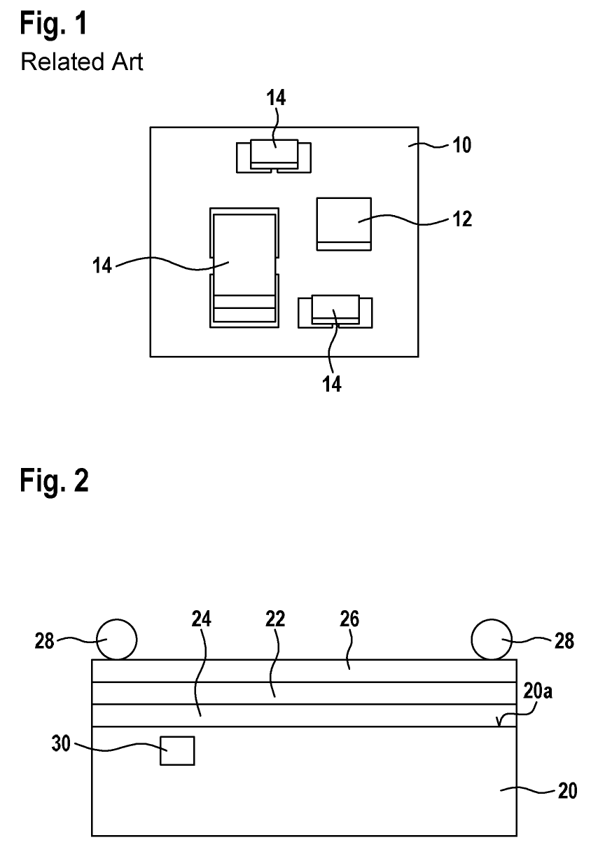

### DETAILED DESCRIPTION OF EXAMPLE EMBODIMENT

FIG. 2 is a schematic representation of a first embodiment of the sensor device of this disclosure.

The sensor device shown schematically in FIG. 2 has a substrate 20 having a substrate surface 20a, which substrate can, in particular, be a semiconductor substrate 20, specifically a silicon substrate 20. A sensor element layer 22 is arranged on and/or above the substrate surface 20a such that the sensor element layer 22 covers the substrate surface 20a and/or at least one intermediate layer 24 at least partially covering the substrate surface 20a. The sensor element layer 22 is designed with at least one sensitive element (not shown) arranged in the sensor element layer 22 such that at least one physical quantity and/or at least one chemical concentration can be measured using the at least one sensitive element of the sensor element layer 22.

The sensor device can therefore be used, for example, as an acceleration, angular rate, gas, humidity and/or pressure sensor device. Preferably, the sensor device can be used (at least) as a magnetic sensor device. If necessary, the at least one sensitive element can be at least one magnetoresistive element, such as at least one TMR element (tunnel magnetoresistance), at least one GMR element and/or at least one AMR element (anisotropic magnetoresistive effect). For example, the at least one magnetoresistive element can be electrically integrated into at least one measurement bridge (not shown) such that a magnetoresistive measurement method for determining a particular magnetic field strength along at least one predetermined spatial direction is possible.

The at least one intermediate layer 24 at least partially covering the substrate surface 20a is, by way of example, (at least) a circuit layer 24 having an application-specific integrated circuit (ASIC). Although not shown in FIG. 2, the sensor device can have at least one further layer in addition to its at least one intermediate layer 24. Preferably, the sensor device also has a redistribution layer 26 (RDL). For example, the redistribution layer 26 can at least partially cover the sensor element layer 22. If desired, at least one solder ball 28 can also be attached to the redistribution layer 26 on a side of the redistribution layer 26 facing away from the substrate 20.

The sensor device shown schematically in FIG. 2 also has at least one capacitor apparatus 30 (shown schematically), which is formed in the substrate 20. This can also be described as an integration of at least one capacitor apparatus 30 into the substrate 20. The integration of the at least one capacitor apparatus 30 into the substrate 20 allows the sensor device to be designed as a chip-scale package which has a substantially smaller volume than a conventional sensor type having a printed circuit board, a sensor mounted on the printed circuit board and at least one additional capacitor mounted on the printed circuit board. The integration of the at least one capacitor apparatus 30 into the substrate 20 thus facilitates miniaturization of the sensor device described here. The resulting miniaturization of the sensor device can be used to save materials, thereby reducing the production costs of the sensor device described here.

The at least one capacitor apparatus 30 can be formed in the substrate 20, in particular by means of deep-trench technology. In this case, the at least one capacitor apparatus 30 can also be referred to as a silicon capacitor. A typical capacitance value of a silicon capacitor in the substrate 20 is typically in the range of 500 nF (nanofarad) to 1 to 2 µF (microfarad). In particular, the capacitance value can range from 100 nF (nanofarad) to 600 nF (nanofarad).

The integration of the at least one capacitor apparatus 30 into the substrate 20 also facilitates the integration of the sensor device into a package, such as, in particular, a mold package. The sensor device described here can therefore also be referred to as a highly integrated wafer-level chip-scale package (highly integrated WLCSP).

The sensor device is preferably designed and/or programmed such that at least one component of the sensor device can be/is powered using a charge temporarily stored on the at least one capacitor apparatus 30. The at least one capacitor apparatus 30 can therefore be used as an energy store/current store for a variety of advantageous uses. Advantageous examples of such uses are described below.

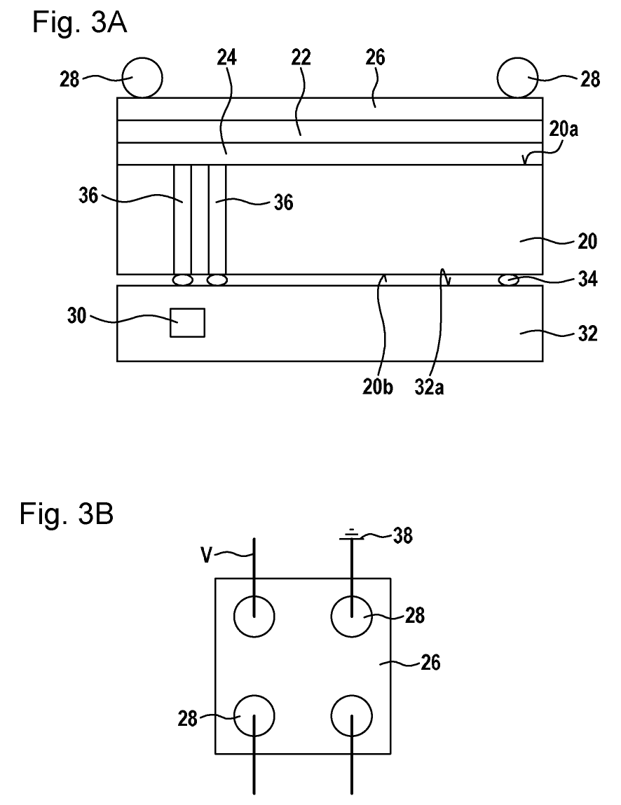

FIG. 3A and 3B are figures schematic representations of a second embodiment of the sensor device.

The sensor device shown schematically in FIG. 3A and 3B differs from the embodiment described above in FIG. 2 in that the at least one capacitor apparatus 30 is formed in a further substrate 32 which is electrically connected to the substrate 20 via at least one bonding connection 34. Although this is not shown in FIG. 3A, at least one (further) capacitor apparatus can also be integrated into the substrate 20.

The at least one bonding connection 34 can be formed, in particular, by means of a eutectic bond or by means of a thermocompression bond between the substrates 20 and 32. Preferably, the at least one bond 34 is a gold-to-gold thermocompression bond, since this type of bond can be formed at a comparatively low temperature, in particular significantly below the Curie temperature. In this way, for example, in the case of at least one magnetoresistive element designed as a sensitive element in the sensor element layer 22, it is ensured that the at least magnetoresistive element remains stably magnetized despite the formation of the at least one bonding connection 34.

As also shown in FIG. 3A, the at least one bonding connection 34, via which the substrate 32 is electrically connected to the substrate 20, can be electrically connected to at least one electrical through-contact (TSV, through-silicon-via) 36 which extends through the substrate 20. The substrate 32 can thus be easily applied to a rear surface 20b of the substrate 20, directed away from the substrate surface 20a, by means of at least one bonding connection 34. Optionally, at least one bonding connection 34 is "sandwiched" between the rear surface 20b and a substrate surface 32a of the substrate 32.

As shown schematically in FIG. 3B, an external supply voltage V and an external ground 38 can each be electrically connected via the at least one solder ball 28 to the at least one capacitor apparatus 30 in the substrate 32. In this way, the at least one capacitor apparatus 30 in the substrate 32 can be charged quickly, with low electrical resistance and reliably.

With respect to further features and properties of the sensor device of FIG. 3A and 3B and their advantages, reference is made to the above description of FIG. 2.

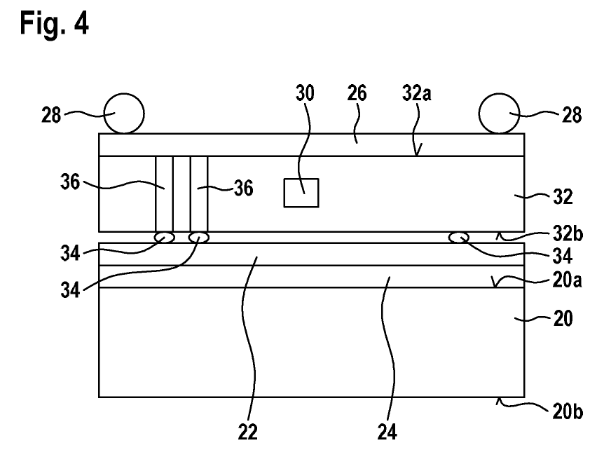

FIG. 4 is a schematic representation of a third embodiment of the sensor device.

In contrast to the above-described embodiment of FIG. 3A and 3B, in the sensor device of FIG. 4 the redistribution layer 26 is formed on the substrate surface 32a of the substrate 32. Mounting the substrate 32 "above" the substrate surface 20a of the substrate 20, which surface is at least partially covered by layers 22 and 24, is facilitated by electrically connecting the at least one bonding connection 34 to at least one electrical through-contact 36 which extends through the substrate 32. In this case, the at least one bonding connection 34 contacts a rear surface 32b of the substrate 32 facing away from the substrate surface 32a, whereby the at least one bonding connection 34 and the layers 22 and 24 are "sandwiched" between the substrate surface 20a and the rear surface 32b.

With respect to further features and properties of the sensor device of FIG. 4 and their advantages, reference is made to the preceding descriptions of FIG. 2, 3A, and 3B.

All of the sensor devices described above achieve the conventional object of equipping the particular sensor device to store/temporarily store energy/current without having to use at least one external capacitor, as in the related art described above. The base area of the sensor devices described above can therefore in each case be smaller than 1.2 x 1.2 mm² (square millimeters). In particular, the base area can be between 0.7 x 0.7 mm² (square millimeters) and 0.9 x 0.9 mm². The space requirement of the sensor devices described above is therefore significantly reduced compared to the related art. The height of the particular sensor device, without the at least one solder ball 28, is typically less than 0.5 mm (millimeters). Furthermore, the production costs for the sensor devices described above are reduced, since the at least one capacitor apparatus 30 integrated into the particular substrate 20 or 32 can be produced more cost-effectively than an external capacitor of corresponding quality class.

All of the sensor devices described above can be produced as a wafer-level chip-scale packages (WLCSP). In all of the sensor devices described above, the at least one capacitor apparatus 30 integrated into the particular substrate 20 or 32 can be designed as what is known as a silicon capacitor by means of deep-trench technology. The silicon capacitor, at least one of which is used, exhibits better reliability over its lifetime compared to conventional capacitors. Furthermore, such a silicon capacitor has a consistently stable capacitance, which is (almost) independent of the current temperature. It is also noted that the sensor devices described above are comparatively temperature resistant, so that they can function reliably even at higher temperatures of at least 125°C. Furthermore, such a silicon capacitor has a virtually constant capacitance even under alternating current and direct current voltages. For these reasons, a silicon capacitor can be designed with a smaller nominal capacitance than a conventional capacitor.

Each of the sensor devices described above can, in particular, be designed as a magnetic sensor device such that, by means of the particular sensor device, a particular magnetic field strength can be determined along at least one predetermined spatial direction. In particular, the particular sensor device can be a 3D magnetic sensor device. The sensor device, designed as a magnetic sensor device, can be used, for example, in a smartphone, a smartwatch or in TWS headphones (true wireless stereo headphones).

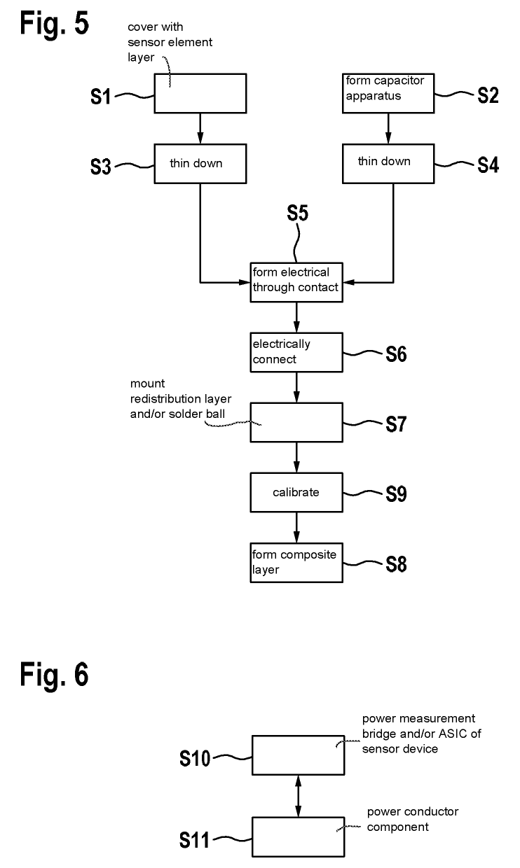

FIG. 5 is a flow chart explaining an embodiment of the production method for a sensor device.

In a method step S1 of the production method described below, a first substrate surface of a first substrate and/or at least one intermediate layer at least partially covering the first substrate surface are covered with a sensor element layer. Furthermore, the sensor element layer is formed in method step S1, with at least one sensitive element arranged therein. Regarding further components that can additionally be formed on and/or in the first substrate, reference is made to the description of the above-described embodiments of sensor devices. Examples of the at least one sensitive element in the sensor element layer have been listed above.

In a further method step S2, at least one capacitor apparatus is formed in the first substrate and/or in a second substrate. The at least one capacitor apparatus is preferably formed in the first substrate and/or in the second substrate by means of deep-trench technology. By way of example only, in the embodiment described here the at least one capacitor apparatus is formed in the second substrate, which is why the production method can also comprise at least one of the (optional) method steps S3 and S4. Optionally, in method step S3, the first substrate can be thinned down, while optionally, in method step S4, the second substrate can be thinned down. The first/second substrate is preferably thinned down to a maximum thickness of between 50 µm (micrometers) and 90 µm (micrometers).

If desired, as method step S5, at least one electrical through-contact can be formed through the first substrate or through the second substrate. If the sensor device produced using the production method described here is formed with the second substrate in addition to the first substrate, then, after carrying out at least the method steps S1 and S2 and, if applicable, also at least one of the method steps S3 to S5, the first substrate is electrically connected to the second substrate via at least one bonding connection as method step S6. Examples of the at least one bonding connection have been mentioned above. Optionally, in method step S7, a redistribution layer and/or at least one solder ball can be mounted on the first substrate and/or on the second substrate.

The method steps S1 to S7 described above can all be carried out at the wafer level by using a first wafer as the first substrate and a second wafer as the second substrate. This allows a plurality of sensor devices to be produced simultaneously, which further reduces their production costs. Optionally, in a final method step S8, the composite wafer formed from the first wafer and the second wafer by means of method step S6 is singulated into the plurality of sensor devices.

A particular advantage of the production method described here is that calibration and/or testing of the sensor devices can be carried out before singulation of the composite wafer. Therefore, before method step S8, a method step S9 can also be carried out, in which, in particular, the at least one later sensor device is calibrated, taking into account its at least one capacitor apparatus, in particular as a final test or final calibration. This would not be possible if such a sensor device were equipped with an external capacitor.

FIG. 6 is a flow chart explaining an embodiment of the operation method for a sensor device.

It is expressly pointed out that the feasibility of the method described below is not limited to the sensor devices explained above. Instead, the method can be carried out with (almost) any sensor device, provided that the particular sensor device is equipped with at least one sensitive element which is arranged in a sensor element layer covering a first substrate surface of a first substrate of the sensor device and/or at least one intermediate layer at least partially covering the first substrate surface.

When carrying out the method described here, at least one component of the sensor device is powered using a charge temporarily stored on at least one capacitor apparatus of the sensor device, wherein the at least one capacitor apparatus is formed in the first substrate and/or in a second substrate which is electrically connected to the first substrate via at least one bonding connection. For example, in a method step S10, at least one measurement bridge having the at least one sensitive element, and/or an application-specific integrated circuit of the sensor device, as the at least one component of the sensor device, can be powered, using a charge temporarily stored on the at least one capacitor apparatus, such that a particular supply voltage of the at least one measurement bridge and/or the application-specific integrated circuit is stabilized.

Alternatively or additionally, in a method step S11 at least one conductor component, as the at least one component of the sensor device, can be powered, using a charge temporarily stored on the at least one capacitor apparatus, such that a magnetic field is generated. Advantageously, by means of the generated magnetic field, for example, a particular polarization of a particular free layer of at least one sensitive element designed as a magnetoresistive element can be generated. This can also be described as what is known as a magnetic reset, by means of which the particular magnetoresistive element can recover from a strong external magnetic field, in particular what is known as a magnetic shock, or by means of which the performance of the sensor device can be optimized. One example of this is what is known as a chopping, i.e., a magnetic reset with alternating current direction, whereby a measurement error attributable to temperature changes or stress changes can be compensated.

What is claimed is:

1. A sensor device, comprising:
at least one first substrate having a first substrate surface;
a sensor element layer including at least one sensitive element arranged in the sensor element layer, wherein the sensor element layer covers: (i) the first substrate surface and/or (ii) at least one intermediate layer at least partially covering the first substrate surface; and
at least one capacitor apparatus, wherein the at least one capacitor apparatus is formed: (i) in the first substrate and/or (ii) in a second substrate which is electrically connected to the first substrate via at least one bonding connection.

2. The sensor device according to claim 1, wherein the sensor device is configured such that at least one component of the sensor device can be powered using a charge temporarily stored on the at least one capacitor apparatus.

3. The sensor device according to claim 2, wherein the sensor device is configured such that at least one measurement bridge having the at least one sensitive element, and/or an application-specific integrated circuit of the sensor device, as the at least one component of the sensor device, can be powered, using a charge temporarily stored on the at least one capacitor apparatus, such that a particular supply voltage of the at least one measurement bridge and/or the application-specific integrated circuit can be stabilized.

4. The sensor device according to claim 1, wherein the at least one capacitor apparatus is formed in the second substrate, and wherein the at least one bonding connection, via which the second substrate is electrically connected to the first substrate, is electrically connected to at least one electrical through-contact which extends through the first substrate or the second substrate.

5. The sensor device according to claim 1, wherein the at least one intermediate layer at least partially covering the first substrate surface includes at least one circuit layer including an application-specific integrated circuit.

6. The sensor device according to claim 1, wherein the sensor device includes a redistribution layer at least partially covering the sensor element layer or a second substrate surface of the second substrate.

7. A production method for a sensor device, comprising the following steps:
covering a first substrate surface of a first substrate and/or at least one intermediate layer at least partially covering the first substrate surface, with a sensor element layer including at least one sensitive element arranged in the sensor element layer; and
forming at least one capacitor apparatus, wherein the at least one capacitor apparatus is formed: (i) in the first substrate and/or (ii) in a second substrate which is or will be electrically connected to the first substrate via at least one bonding connection.

8. The production method according to claim 7, wherein the at least one capacitor apparatus is formed, using deep-trench technology, in the first substrate and/or in the second substrate.

9. An operation method for a sensor device which includes at least one sensitive element arranged in a sensor element layer covering: (i) a first substrate surface of a first substrate of the sensor device and/or (ii) at least one intermediate layer at least partially covering the first substrate surface, comprising the following step:
powering at least one component of the sensor device using a charge temporarily stored on at least one capacitor apparatus of the sensor device;
wherein the at least one capacitor apparatus is formed in the first substrate and/or in a second substrate which is electrically connected to the first substrate via at least one bonding connection.

10. The method according to claim 9, wherein at least one conductor component, as the at least one component of the sensor device, is powered using a charge temporarily stored on the at least one capacitor apparatus such that a magnetic field is generated, using which a particular polarization of a particular free layer of the at least one sensitive element configured as a magnetoresistive element is generated.

11. The method according to claim 9, wherein at least one measurement bridge having the at least one sensitive element, and/or an application-specific integrated circuit of the sensor device, as the at least one component of the sensor device, is powered, using a charge temporarily stored on the at least one capacitor apparatus, such that a particular supply voltage of the at least one measurement bridge and/or the application-specific integrated circuit is stabilized.
